(19) United States
(12) Patent Application Publication
(10) Pub. No.: US 2023/0395322 A1
(43) Pub. Date: Dec. 7, 2023

(54) MULTILAYER CERAMIC CAPACITOR AND MULTILAYER CERAMIC CAPACITOR MOUNTED STRUCTURE

(71) Applicant: SAMSUNG ELECTRO-MECHANICS CO., LTD., Suwon-si (KR)

(72) Inventors: Soohwan Son, Suwon-si (KR); Mansu Byun, Suwon-si (KR)

(73) Assignee: SAMSUNG ELECTRO-MECHANICS CO., LTD., Suwon-si (KR)

(21) Appl. No.: 18/098,284

(22) Filed: Jan. 18, 2023

(30) Foreign Application Priority Data
Jun. 2, 2022 (KR) 10-2022-0067437

(51) Int. Cl. H01G 2/06; H05K 1/18; H01G 4/30; H01G 4/248

(52) U.S. Cl. CPC H01G 2/06; H05K 1/183; H01G 4/30; H01G 4/248; H05K 2201/10015

(57) ABSTRACT

A multilayer ceramic capacitor mounted structure relates to a structure in which a multilayer ceramic capacitor is mounted on a circuit board through electrode pads. The multilayer ceramic capacitor may include: a ceramic body including a plurality of dielectric layers stacked with a length, a width, and a thickness of a preset size; external electrodes spaced apart from each other along a longitudinal direction of the ceramic body, each of the external electrodes being disposed on at least opposite sides in a width direction of the ceramic body; and a plurality of internal electrodes alternately stacked with the dielectric layers therebetween and respectively connected to the external electrodes in the ceramic body, and edges of the external electrodes may be aligned with outer edges of the electrode pads or positioned at least more outwardly than the outer edges of the electrode pads, at opposite ends along the longitudinal direction of the ceramic body.

### CROSS-REFERENCE TO RELATED APPLICATION

This application claims the benefit of priority to Korean Patent Application No. 10-2022-0067437, filed on Jun. 2, 2022 in the Korean Intellectual Property Office, the entire contents of which are incorporated herein by reference.

### BACKGROUND

### (a) Technical Field

The present disclosure relates to a multilayer ceramic capacitor and a structure in which the multilayer ceramic capacitor is mounted.

### (b) Description of the Related Art

Electronic components using ceramic materials include capacitors, inductors, piezoelectric elements, varistors, or thermistors. Among such ceramic electronic components, a multilayer ceramic capacitor (MLCC) may be used in various electronic devices due to its small size, high capacity, and easy mounting.

For example, the multilayer ceramic capacitor may be used for chip-type capacitors that are mounted in boards of various electronic products to charge or discharge electricity, including imaging devices such as liquid crystal displays (LCD), plasma display panels (PDP), and organic light-emitting diode (OLED) displays, computers, personal portable terminals, and smartphones.

The multilayer ceramic capacitor may have a structure in which a plurality of dielectric material layers and internal electrodes of different polarities between the dielectric material layers are alternately arranged. In this case, the dielectric layers are piezoelectric, and thus when a DC or AC voltage is applied to the multilayer ceramic capacitor, a piezoelectric phenomenon occurs between the internal electrodes, thereby generating periodic vibrations while expanding and contracting a volume of ceramic bodies thereof depending on a frequency.

Such vibrations are transferred to a substrate through external electrodes of the multilayer ceramic capacitor and solders connecting the external electrodes and the substrate, and thus the entire substrate may become an acoustic reflective surface, thereby generating a vibrating sound that becomes noise. Such a vibrating sound may correspond to an audible frequency in a range of 20 to 20,000 Hz that is unpleasant to a person, and this vibrating sound that is unpleasant to a person is called acoustic noise.

Furthermore, in recent electronic devices, since mechanical components are being quieted, acoustic noise generated by the multilayer ceramic capacitor may be more prominent as described above. This failure of the acoustic noise may be identified as a malfunction of the device because a user considers the acoustic noise to be a strange sound when an operating environment of the device is quiet. In addition, in a device having a voice circuit, a problem of deterioration of the device may occur as acoustic noise is superimposed on a voice output.

The above information disclosed in this Background section is only for enhancement of understanding of the background of the disclosure, and therefore, it may contain information that does not form the prior art that is already known in this country to a person of ordinary skill in the art.

### SUMMARY

An embodiment has been made in an effort to provide a multilayer ceramic capacitor mounted structure with reduced acoustic noise and a multilayer ceramic capacitor applied thereto.

However, the problem to be solved by the exemplary embodiments of the present disclosure is not limited to the above-described problems, and can be variously extended within the scope of the technical spirit included in the present disclosure.

A multilayer ceramic capacitor mounted structure according to an embodiment relates to a multilayer ceramic capacitor mounted structure in which multilayer ceramic capacitors are mounted in an upper surface of a circuit board through first and second electrode pads. The multilayer ceramic capacitor may include: a ceramic body including a plurality of dielectric layers stacked on one another and having a preset size with a length, a width, and a thickness along directions crossing each other; first and second external electrodes spaced apart from each other along a longitudinal direction of the ceramic body, each of the first and second external electrodes being disposed on at least opposite sides in a width direction of the ceramic body; and a plurality of first and second internal electrodes alternately stacked with the dielectric layers therebetween and respectively connected to the first and second external electrodes in the ceramic body, and edges of the first and second external electrodes may be aligned with outer edges of the first and second electrode pads or positioned at least more outwardly than the outer edges of the first and second electrode pads, at opposite ends along the longitudinal direction of the ceramic body.

The first and second electrode pads may not be formed outside opposite edges of the multilayer ceramic capacitor in the longitudinal direction.

Each of the first and second electrode pads may include a pair of patches that are separated from each other based on a center of the ceramic body in a width direction of the ceramic body.

The first and second external electrodes may be bonded to the first and second electrode pads, respectively, by a conductive bonding member at opposite sides in a width direction of the ceramic body.

The first and second internal electrodes may be positioned to be offset from each other in the longitudinal direction of the ceramic body to be alternately drawn out from opposite end portions thereof, the first and second external electrodes may each include a body portion covering the opposite end surfaces of the ceramic body in the longitudinal direction, and a band portion extending from the body portion along at least a side surface of the ceramic body, and the band portions of the first and second external electrodes may be bonded to the first and second electrode pads, respectively, by the conductive bonding member.

The multilayer ceramic capacitor may further include an insulating layer formed to cover outside of the body portion of each of the first and second external electrodes.

The conductive bonding member may not be positioned outside the body portions of the first and second external electrodes on which the insulating layer is formed.

The band portions of the first and second external electrodes may extend from the respective body portions to cover portions of upper and lower surfaces that face each other in a thickness direction of the ceramic body, and the insulating layer may extend to cover the band portions of the first and second external electrodes disposed on the upper and lower surfaces of the ceramic body.

The band portions of the first and second external electrodes may expose portions of upper and lower surfaces of the ceramic body facing each other in a thickness direction of the ceramic body.

The insulating layer may be made of at least one material selected from a group including insulating glass, epoxy, and insulating ceramic.

The first internal electrode may include a first main surface portion and a first lead portion drawn out from the first main surface portion to opposite side surfaces of the ceramic body in the width direction and connected to the first external electrode, and the second internal electrode includes a second main surface portion and a second lead portion drawn out from the second main surface portion to the opposite side surfaces of the ceramic body in the width direction and connected to the second external electrode.

The first and second external electrodes may be formed on at least one of upper and lower surfaces of the ceramic body facing each other in a thickness direction of the ceramic body and on opposite side surfaces of the ceramic body.

The first and second external electrodes may not be disposed outside of portions of the opposite end surfaces of the ceramic body facing in the longitudinal direction.

Another embodiment of the present disclosure provides a multilayer ceramic capacitor including: a ceramic body including a plurality of dielectric layers stacked on one another and having a preset size with a length, a width, and a thickness along directions crossing each other; first and second external electrodes spaced apart from each other along a longitudinal direction of the ceramic body, each of the first and second external electrodes including a body portion covering one of opposite end surfaces of the ceramic body in the longitudinal direction, and a band portion extending from the body portion to cover portions of upper and lower surfaces that face each other in a thickness direction of the ceramic body; a plurality of first and second internal electrodes alternately stacked with the dielectric layers therebetween in the ceramic body, positioned to be offset from each other in the longitudinal direction of the ceramic body to be alternately drawn out from opposite end portions thereof, and respectively connected to the first and second external electrodes; and an insulating layer disposed to cover outside of the body portions of the first and second external electrodes, and extending to cover the band portions of the first and second external electrodes formed on upper and lower surfaces of the ceramic body.

The band portions of the first and second external electrodes may further extend to cover opposite side surfaces of the ceramic body facing each other in a width direction of the ceramic body, and may be exposed without being covered with the insulating layer in the width direction.
the insulating layer is made of at least one material selected from a group including insulating glass, epoxy, and insulating ceramic.

In accordance with a multilayer ceramic capacitor mounted structure according to an embodiment, when mounting a multilayer ceramic capacitor in a board, a source of acoustic noise can be removed by setting an attachment area in consideration of a direction of expansion and contraction of a ceramic body depending on driving of the multilayer ceramic capacitor.

As described above, it is possible to reduce the acoustic noise of the multilayer ceramic capacitor mounted structure by limiting an area where the multilayer ceramic capacitor is attached to a substrate.

### BRIEF DESCRIPTION OF THE DRAWINGS

FIG. 1 illustrates a schematic perspective view showing a multilayer ceramic capacitor according to an embodiment.

FIG. 2 illustrates a cross-sectional view taken along a line II-II′ of FIG. 1.

FIG. 3 illustrates a perspective view showing a form in which the multilayer ceramic capacitor illustrated in FIG. 1 is mounted on a substrate.

FIG. 4 illustrates a side view showing a multilayer ceramic capacitor mounted structure illustrated in FIG. 3.

FIG. 5 illustrates a top plan view showing the multilayer ceramic capacitor mounted structure illustrated in FIG. 3.

FIG. 6 illustrates a perspective view showing a form in which a multilayer ceramic capacitor according to another embodiment is mounted on a substrate.

FIG. 7 illustrates a perspective view showing a form in which a multilayer ceramic capacitor according to another embodiment is mounted on a substrate.

FIG. 8 illustrates a perspective view showing a form in which a multilayer ceramic capacitor according to another embodiment is mounted on a substrate.

FIG. 9 illustrates a top plan view showing a multilayer ceramic capacitor mounted structure illustrated in FIG. 8.

FIG. 10 illustrates a perspective view showing a form in which a multilayer ceramic capacitor according to another embodiment is mounted on a substrate.

FIG. 11 and FIG. 12 each illustrate an exploded perspective view showing an internal electrode structure of the multilayer ceramic capacitor illustrated in FIG. 10.

### DETAILED DESCRIPTION OF THE EMBODIMENTS

Hereinafter, an embodiment of the present disclosure will be described in detail so that a person of ordinary skill in the technical field to which the present disclosure belongs can easily implement it with reference to the accompanying drawings. The drawings and description are to be regarded as illustrative in nature and not restrictive. Like reference numerals designate like elements throughout the specification. In addition, some constituent elements in the accompanying drawings are exaggerated, omitted, or schematically illustrated, and the size of each constituent element does not fully reflect the actual size.

The accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

Terms including ordinal numbers such as first, second, and the like will be used only to describe various components, and are not to be interpreted as limiting these components. The terms are only used to differentiate one component from other components.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

It will be further understood that terms “comprises/includes” or “have” used throughout the specification specify the presence of stated features, numerals, steps, operations, components, parts, or a combination thereof, but do not preclude the presence or addition of one or more other features, numerals, steps, operations, components, parts, or a combination thereof. Accordingly, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, “connected” means that two or more components are not only directly connected, but two or more components may be connected indirectly through other components, physically connected as well as being electrically connected, or it may be referred to by different names depending on the location or function, but may mean integral.

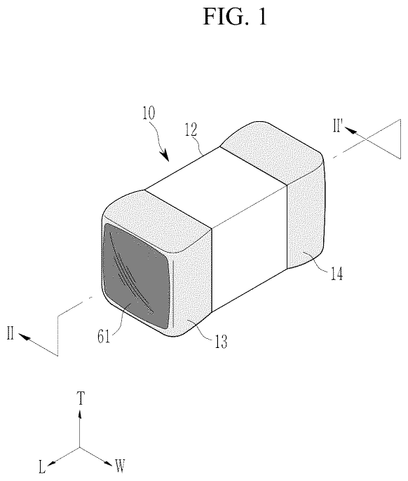

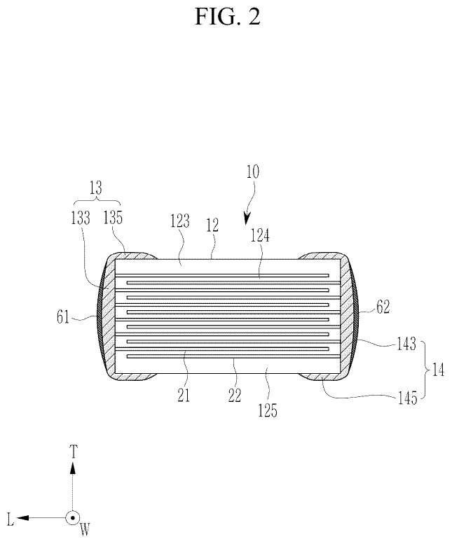

FIG. 1 illustrates a schematic perspective view showing a multilayer ceramic capacitor according to an embodiment, and FIG. 2 illustrates a cross-sectional view taken along a line II-II′ of FIG. 1.

Referring to FIG. 1 and FIG. 2, the multilayer ceramic capacitor 10 according to the present embodiment includes a ceramic body 12, first and second external electrodes 13 and 14, and a plurality of first and second internal electrodes 21 and 22.

The ceramic body 12 may be formed by stacking a plurality of dielectric layers 124 in a thickness direction T and then firing it. Herein, each of the dielectric layers 124 adjacent to each other in the ceramic body 12 may be integrated with each other in a state where boundaries are unclear. The ceramic body 12 may be formed in a substantially hexahedral shape having a length, a width, and a thickness of a preset size along directions crossing each other, but the present disclosure is not limited thereto.

In the present embodiment, for better understanding and ease of description, surfaces facing each other in the thickness direction T on which the dielectric layers 124 of the ceramic body 12 are stacked are defined as an upper surface and a lower surface, surfaces facing each other in a longitudinal direction L of the ceramic body 12 connecting the upper and lower surfaces are defined as first and second end surfaces, and surfaces facing each other in a width direction W that is perpendicular to the first and second end surfaces are defined as first and second side surfaces.

Meanwhile, in the ceramic body 12, an upper cover layer 123 of a predetermined thickness may be disposed on an uppermost inner electrode, and a lower cover layer 125 may be disposed under a lowermost inner electrode. In this case, the upper cover layer 123 and the lower cover layer 125 may have a same composition as the dielectric material layer 124, and at least one dielectric layer including no internal electrode may be stacked on each of the uppermost internal electrode and the lowermost internal electrode of the ceramic body 12.

The dielectric layer 124 may include a high dielectric constant ceramic material, e.g., BaTiO₃ (barium titanate)-based ceramic powder, but the present disclosure is not limited thereto. Examples of the BaTiO₃ (barium titanate)-based ceramic powder may include (Ba₁₋ₓCaₓ)TiO₃, Ba(Ti_{1-y}Ca_{y})O₃, (Ba₁₋ₓCaₓ)(Ti_{1-y}Zr_{y})O₃, Ba(Ti_{1-y}Zr_{y})O₃, or the like in which Ca (calcium), Zr (zirconium), etc. are partially dissolved in BaTiO₃, but the present disclosure is not limited thereto.

In addition, the dielectric layer 124 may further include at least one of a ceramic additive, an organic solvent, a plasticizer, a binder, or a dispersant. As the ceramic additive, a transition metal oxide or carbide, a rare earth element, magnesium (Mg), or aluminum (Al) may be used.

The first and second external electrodes 13 and 14 are positioned at opposite end portions of the ceramic body 12 in the longitudinal direction L, and include first and second body portions 133 and 143 and first and second band portions 135 and 145, respectively. The first and second body portions 133 and 143 cover the first and second end surfaces of the ceramic body 12 in the longitudinal direction, respectively, and are electrically connected to exposed ends of the first and second internal electrodes 21 and 22, respectively. The first and second band portions 135 and 145 respectively extend from the first and second body portions 133 and 143 to cover a portion of the circumferential surface (upper and lower surfaces and first and second side surfaces) of the ceramic body 12.

In the present embodiment, insulating layers 61 and 62 may be disposed on the first and second body portions 133 and 143 of the first and second external electrodes 13 and 14. The insulating layers 61 and 62 may be formed to partially or completely cover outer sides of the first and second body portions 133 and 143, and may have 70% to 101% of an area of the first and second body portions 133 and 143. The insulating layers 61 and 62 may be formed along shapes of the first and second body portions 133 and 143, and may have, e.g., a rectangular shape. The insulating layers 61 and 62 are made of an insulating material, and for example, may be made of at least one material selected from a group including insulating glass, epoxy, and insulating ceramic.

The first and second internal electrodes 21 and 22 are alternately stacked with a dielectric material layer 124 provided therebetween. The first and second internal electrodes 21 and 22 may be formed and stacked on a ceramic sheet forming the dielectric layer 124, and then may be alternately positioned in the ceramic body 12 in the thickness direction with one dielectric layer 124 provided therebetween by firing. The first and second internal electrodes 21 and 22, which are electrodes having different polarities, may be positioned to face each other in a stacking direction of the dielectric layers 124, and may be electrically insulated from each other by the dielectric layer 124 disposed in the middle.

The first and second internal electrodes 21 and 22 are positioned to be offset from each other in the longitudinal direction with the dielectric layer 124 provided therebetween, and first ends thereof are exposed through the first and second end surfaces of the ceramic body 12 in the longitudinal direction, respectively. As such, end portions of the first and second internal electrodes 21 and 22 alternately exposed through the first and second end surfaces of the ceramic body 12 in the longitudinal direction may be electrically connected to the first and second body portions 133 and 143 of the first and second external electrodes 13 and 14 at first and second end surfaces of the ceramic body 12 in the longitudinal direction, respectively. In addition, the first and second internal electrodes 21 and 22 may be formed of a conductive metal, and for example, a material such as nickel (Ni) or a nickel (Ni) alloy may be used, but the present disclosure is not limited thereto.

Depending on the above configuration, when a predetermined voltage is applied to the first and second external electrodes 13 and 14, electric charges are accumulated between the first and second internal electrodes 21 and 22 facing each other. In this case, capacitance of the multilayer ceramic capacitor is proportional to an overlapping area of the first and second internal electrodes 21 and 22 overlapping each other along the stacking direction of the dielectric layer 124.

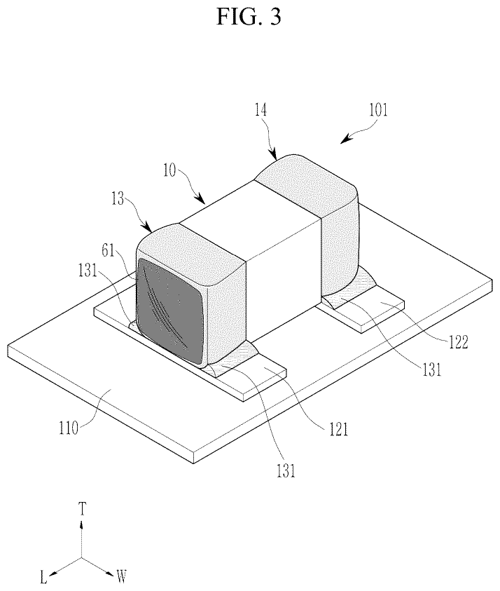

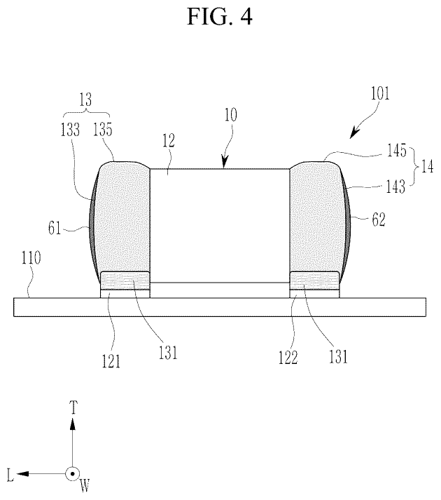

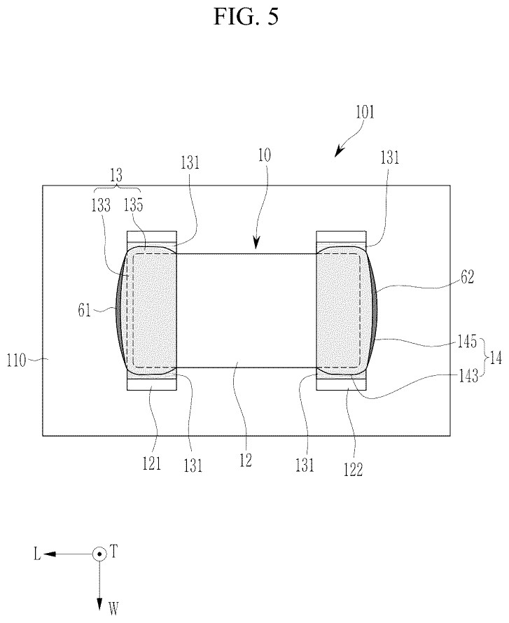

FIG. 3 illustrates a perspective view showing a form in which the multilayer ceramic capacitor illustrated in FIG. 1 is mounted on a substrate, FIG. 4 illustrates a side view showing a multilayer ceramic capacitor mounted structure illustrated in FIG. 3, and FIG. 5 illustrates a top plan view showing the multilayer ceramic capacitor mounted structure illustrated in FIG. 3.

Referring to FIG. 3 to FIG. 5, the multilayer ceramic capacitor mounted structure 101 according to the present embodiment includes a circuit board 110 in which the multilayer ceramic capacitor 10 is mounted, and first and second electrode pads 121 and 122 disposed on an upper surface thereof. The multilayer ceramic capacitor 10 may be mounted on the circuit board 110 through the first and second electrode pads 121 and 122. The multilayer ceramic capacitor 10 may have the structure described with reference to FIG. 1 and FIG. 2.

The first and second electrode pads 121 and 122 may be positioned to be spaced apart from each other on the upper surface of the circuit board 110, and the first and second band portions 135 and 145 of the first and second external electrodes 13 and 14 of the multilayer ceramic capacitor 10 may be spaced apart from each other. The first and second band portions 135 and 145 of the multilayer ceramic capacitor 10 may be fixed to the circuit board 110 by using a conductive bonding member 131 in a state in which they are placed in contact with the first and second electrode pads 121 and 122, and accordingly, the multilayer ceramic capacitor 10 may be electrically connected to the first and second electrode pads 121 and 122 of the circuit board 110. The conductive bonding member 131 may include solder, for example.

According to the present embodiment, at opposite ends along the longitudinal direction L of the ceramic body 12, edges of the first and second external electrodes 13 and 14 may be aligned with the outer edges of the first and second electrode pads 121 and 122, and at least the first and second electrode pads 121 and 122 may be positioned more outside than outer edges thereof. That is, the first and second electrode pads 121 and 122 may be positioned to be included in a region that is set between the opposite edges of the multilayer ceramic capacitor 10 in the longitudinal direction L of the ceramic body 12. In this case, the first and second electrode pads 121 and 122 may not be disposed outside the opposite edges of the multilayer ceramic capacitor 10 in the longitudinal direction. On the other hand, the first and second electrode pads 121 and 122 may be disposed to extend outwardly from opposite edges of the multilayer ceramic capacitor 10 in the width direction W of the ceramic body 12.

Herein, ‘outside’ refers to a direction from a center of a region in which the ceramic body 12 is positioned on the circuit board 110 toward the outside of the region, and this is also true of other embodiments below.

In the present embodiment, the first and second external electrodes 13 and 14 of the multilayer ceramic capacitor 10 are respectively mounted in the circuit board 110 by being fixed to the first and second electrode pads 121 and 122 by the conductive bonding member 131 on opposite side surfaces facing each other in the width direction W of the ceramic body 12. In this case, the first and second electrode pads 121 and 122 do not have portions facing the first and second body portions 133 and 143 of the first and second external electrodes 13 and 14, and thus the conductive bonding member 131 may not be disposed on opposite end surfaces of the ceramic body 12 facing in the longitudinal direction L.

In addition, the multilayer ceramic capacitor 10 includes insulating layers 61 and 62 disposed to cover the outside of the first and second body portions 133 and 143 of the first and second external electrodes 13 and 14. When the multilayer ceramic capacitor 10 is mounted in the circuit board 110, the insulating layers 61 and 62 prevent the conductive bonding member 131 from being formed on the first and second body portions 133 and 143 of the first and second external electrodes 13 and 14.

Accordingly, the first and second electrode pads 121 and 122 may be bonded to the first and second band portions 135 and 145 of the first and second external electrodes 13 and 14 using the conductive bonding member 131, but the conductive bonding member 131 may not be provided between the first and second electrode pads 121 and 122 and the first and second body portions 133 and 143 of the first and second external electrodes 13 and 14, and the first and second body portions 133 and 143 may not be connected to the first and second electrode pads 121 and 122.

When a voltage is applied while the multilayer ceramic capacitor 10 is mounted in the circuit board 110, acoustic noise may occur. Sizes and shapes of the first and second electrode pads 121 and 122 may control amounts and positions of the conductive bonding member 131 connecting the first and second external electrodes 13 and 14 and the first and second electrode pads 121 and 122 of the multilayer ceramic capacitor 10, and accordingly, a magnitude of the acoustic noise may be adjusted.

When voltages having different polarities are applied to the first and second external electrodes 13 and 14 disposed on the first and second end surfaces of the ceramic body 12 in the longitudinal direction in a state in which the multilayer ceramic capacitor 10 is mounted in the circuit board 110, the ceramic body 12 expands and contracts in a thickness direction by an inverse piezoelectric effect of the dielectric layer 124. In this case, the first and second end surfaces of the ceramic body 12 in the longitudinal direction on which the first and second external electrodes 13 and 14 are formed contract and expand as opposed to the expansion and contraction in the thickness direction of the ceramic body 12 due to the Poisson effect.

Therefore, even when a voltage is applied to the multilayer ceramic capacitor 10 to allow the ceramic body 12 to repeat expansion and contraction in the thickness direction, the first and second end surfaces of the ceramic body 12 may not be fixed to the circuit board 110, thereby reducing occurrence of acoustic noise.

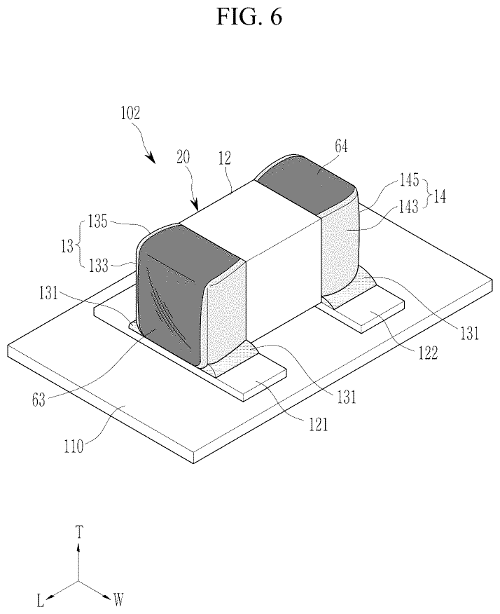

FIG. 6 illustrates a perspective view showing a form in which a multilayer ceramic capacitor according to another embodiment is mounted on a substrate.

Referring to FIG. 6, the multilayer ceramic capacitor 20 applied to the multilayer ceramic capacitor mounted structure 102 according to the present embodiment includes first and second external electrodes 13 and 14 positioned at opposite ends of a ceramic body 22 in the longitudinal direction, and the first and second external electrodes 13 and 14 include first and second body portions 133 and 143 and first and second band portions 135 and 145, respectively.

In addition, the multilayer ceramic capacitor mounted structure 102 includes a circuit board 110 in which the multilayer ceramic capacitor 20 is mounted, and first and second electrode pads 121 and 122 disposed on an upper surface thereof. The multilayer ceramic capacitor 20 may be mounted on the circuit board 110 through the first and second electrode pads 121 and 122.

In the present embodiment, the multilayer ceramic capacitor 20 includes insulating layers 63 and 64 disposed to cover the outside of the first and second body portions 133 and 143 of the first and second external electrodes 13 and 14. In addition, the insulating layers 63 and 64 may extend up and down to cover the first and second band portions 135 and 145 disposed on upper and lower surfaces of the ceramic body 22 facing each other in the thickness direction T. When the multilayer ceramic capacitor 20 is mounted in the circuit board 110, the insulating layers 63 and 64 prevent the conductive bonding member 131 from being disposed on the first and second body portions 133 and 143 of the first and second external electrodes 13 and 14. In this case, the band portions 135 and 145 of the first and second external electrodes 13 and 14 covering opposite side surfaces of the ceramic body 22 facing each other in a width direction may be exposed without being covered with the insulating layers 63 and 64.

According to the present embodiment, at opposite ends along the longitudinal direction L of the ceramic body 12, edges of the first and second external electrodes 13 and 14 may be aligned with the outer edges of the first and second electrode pads 121 and 122, and at least the first and second electrode pads 121 and 122 may be positioned more outside than outer edges thereof. That is, the first and second electrode pads 121 and 122 may be positioned to be included in a region that is set between the opposite edges of the multilayer ceramic capacitor 20 in a longitudinal direction of the ceramic body 12. In this case, the first and second electrode pads 121 and 122 may not be disposed outside the opposite edges of the multilayer ceramic capacitor 10 in the longitudinal direction. On the other hand, the first and second electrode pads 121 and 122 may be formed to extend outwardly from the opposite edges of the multilayer ceramic capacitor 20 in the width direction W of the ceramic body 12.

Accordingly, the first and second electrode pads 121 and 122 may be bonded to the first and second band portions 135 and 145 of the first and second external electrodes 13 and 14 on the opposite side surfaces of the ceramic body 22 along the width direction by using the conductive bonding member 131. On the other hand, the conductive bonding member 131 may not be provided between the first and second electrode pads 121 and 122 and the first and second body portions 133 and 143 of the first and second external electrodes 13 and 14, and the first and second body portions 133 and 143 may not be connected to the first and second electrode pads 121 and 122.

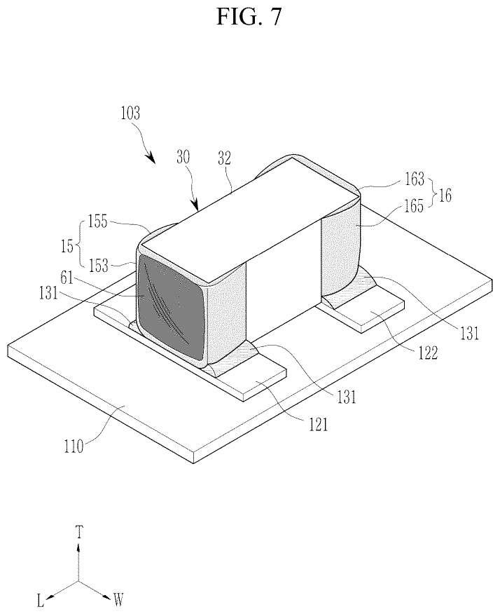

FIG. 7 illustrates a perspective view showing a form in which a multilayer ceramic capacitor according to another embodiment is mounted on a substrate.

Referring to FIG. 7, the multilayer ceramic capacitor 30 applied to the multilayer ceramic capacitor mounted structure 103 according to the present embodiment includes first and second external electrodes 15 and 16 positioned at opposite ends of a ceramic body 32 in the longitudinal direction L, and the first and second external electrodes 15 and 16 include first and second body portions 153 and 163 and first and second band portions 155 and 165, respectively.

In addition, the multilayer ceramic capacitor mounted structure 103 includes a circuit board 110 in which the multilayer ceramic capacitor 30 is mounted, and first and second electrode pads 121 and 122 disposed on an upper surface thereof. The multilayer ceramic capacitor 30 may be mounted on the circuit board 110 through the first and second electrode pads 121 and 122.

In the present embodiment, the first and second band portions 155 and 165 extend to cover portions of opposite side surfaces of the ceramic body 32 facing each other in the width direction W, while the ceramic body 32 is formed to expose upper and lower surfaces facing each other in the thickness direction T. Accordingly, the first and second band portions 155 and 165 may not extend onto the upper and lower surfaces of the ceramic body 32, but may be formed on the opposite side surfaces thereof.

According to the present embodiment, at opposite ends along the longitudinal direction L of the ceramic body 32, edges of the first and second external electrodes 15 and 16 may be aligned with the outer edges of the first and second electrode pads 121 and 122, and at least the first and second electrode pads 121 and 122 may be positioned more outside than outer edges thereof. That is, the first and second electrode pads 121 and 122 may be positioned to be included in a region that is set between the opposite edges of the multilayer ceramic capacitor 30 in a longitudinal direction of the ceramic body 32. In this case, the first and second electrode pads 121 and 122 may not be formed outside the opposite edges of the multilayer ceramic capacitor 30 in the longitudinal direction. On the other hand, the first and second electrode pads 121 and 122 may be formed to extend outwardly from the opposite edges of the multilayer ceramic capacitor 30 in the width direction W of the ceramic body 32.

In the meantime, the multilayer ceramic capacitor 30 includes insulating layers 61 and 62 disposed to cover the outside of the first and second body portions 153 and 163 of the first and second external electrodes 15 and 16. When the multilayer ceramic capacitor 30 is mounted in the circuit board 110, the insulating layers 61 and 62 prevent the conductive bonding member 131 from being formed on the first and second body portions 153 and 163 of the first and second external electrodes 15 and 16.

Accordingly, the first and second electrode pads 121 and 122 may be bonded to the first and second band portions 155 and 165 of the first and second external electrodes 15 and 16 using the conductive bonding member 131, but the conductive bonding member 131 may not be provided between the first and second electrode pads 121 and 122 and the first and second body portions 153 and 163 of the first and second external electrodes 15 and 16, and the first and second body portions 153 and 163 may not be connected to the first and second electrode pads 121 and 122.

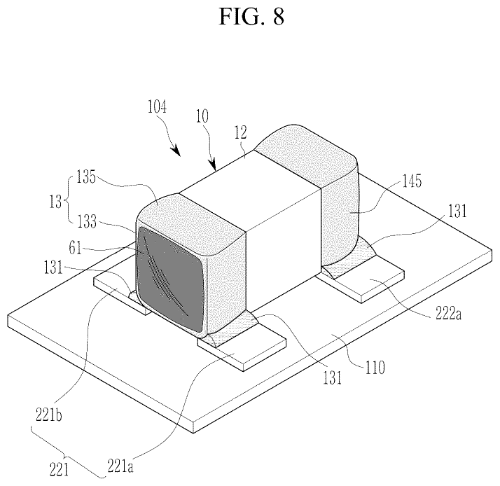

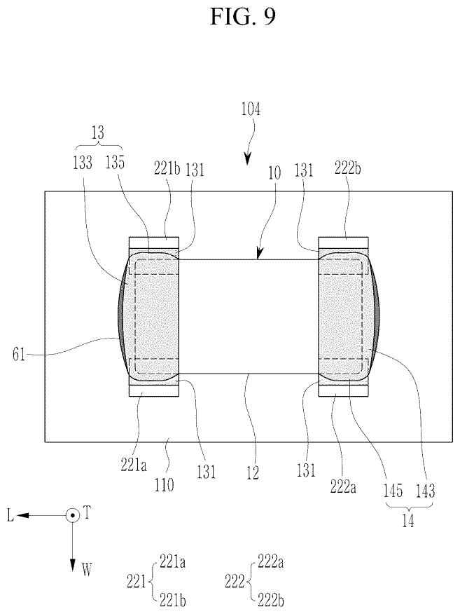

FIG. 8 illustrates a perspective view showing a form in which a multilayer ceramic capacitor according to another embodiment is mounted on a substrate, and FIG. 9 illustrates a top plan view showing a multilayer ceramic capacitor mounted structure illustrated in FIG. 8.

Referring to FIG. 8 and FIG. 9, the multilayer ceramic capacitor 10 applied to the multilayer ceramic capacitor mounted structure 104 according to the present embodiment includes first and second external electrodes 13 and 14 positioned at opposite ends of a ceramic body 12 in the longitudinal direction, and the first and second external electrodes 13 and 14 include first and second body portions 133 and 143 and first and second band portions 135 and 145, respectively.

In addition, the multilayer ceramic capacitor mounted structure 104 includes a circuit board 110 in which the multilayer ceramic capacitor 10 is mounted, and first and second electrode pads 221 and 222 respectively formed as a pair of patches on an upper surface thereof. The multilayer ceramic capacitor 10 may be mounted on the circuit board 110 through the first and second electrode pads 221 and 222.

In the first and second electrode pads 221 and 222, the first and second band portions 135 and 145 of the multilayer ceramic capacitor 10 are spaced apart from each other, and a pair of patches 221a and 221b, and 222a and 222b, constituting each of the first and second electrode pads 221 and 222 may be separated from each other based on a center of the ceramic body 12 in the width direction. That is, the patches 221a, 221b, 222a, and 222b constituting the first and second electrode pads 221 and 222 may be positioned to respectively correspond to four corners of a lower surface of the multilayer ceramic capacitor 10, to contact the first and second band portions 135 and 145 of the multilayer ceramic capacitor 10.

According to the present embodiment, at opposite ends along the longitudinal direction L of the ceramic body 12, edges of the first and second external electrodes 13 and 14 may be aligned with outer edges of the pair of patches 221a and 221b, and 222a and 222b, constituting the first and second electrode pads 221 and 222, respectively, and may be positioned more outwardly than at least the outer edges of these patches 221a, 221b, 222a, and 222b. That is, the first and second electrode pads 221 and 222 may be positioned to be included in a region that is set between the opposite edges of the multilayer ceramic capacitor 10 in a longitudinal direction of the ceramic body 12. In this case, the first and second electrode pads 221 and 222 may not be formed outside the opposite edges of the multilayer ceramic capacitor 10 in the longitudinal direction. On the other hand, the first and second electrode pads 221 and 222 may be formed to extend outwardly from the opposite edges of the multilayer ceramic capacitor 10 in the width direction W.

In the meantime, the multilayer ceramic capacitor 10 includes insulating layers 61 and 62 disposed to cover the outside of the first and second body portions 133 and 143 of the first and second external electrodes 13 and 14. When the multilayer ceramic capacitor 10 is mounted in the circuit board 110, the insulating layers 61 and 62 prevent the conductive bonding member 131 from being formed on the first and second body portions 133 and 143 of the first and second external electrodes 13 and 14.

Accordingly, the first and second electrode pads 221 and 222 may be bonded to the first and second band portions 135 and 145 of the first and second external electrodes 13 and 14 using the conductive bonding member 131, but the conductive bonding member 131 may not be provided between the first and second electrode pads 221 and 222 and the first and second body portions 133 and 143 of the first and second external electrodes 13 and 14, and the first and second body portions 133 and 143 may not be connected to the first and second electrode pads 221 and 222.

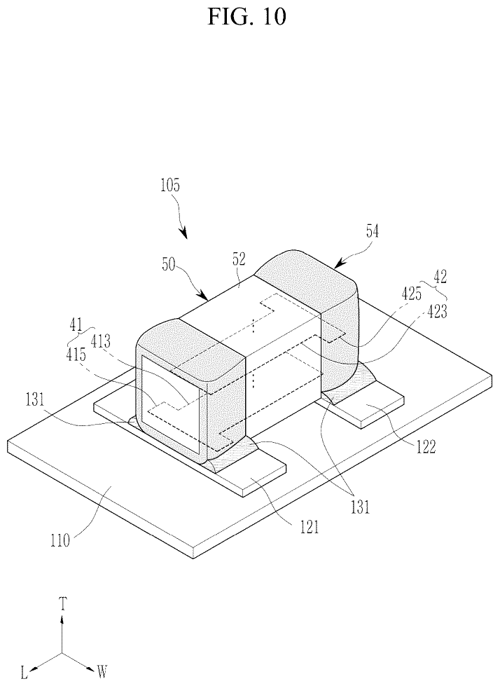

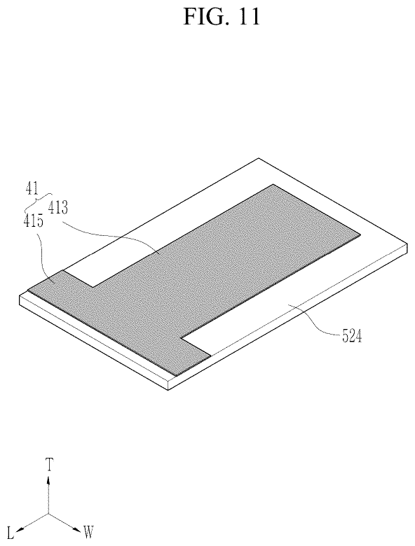

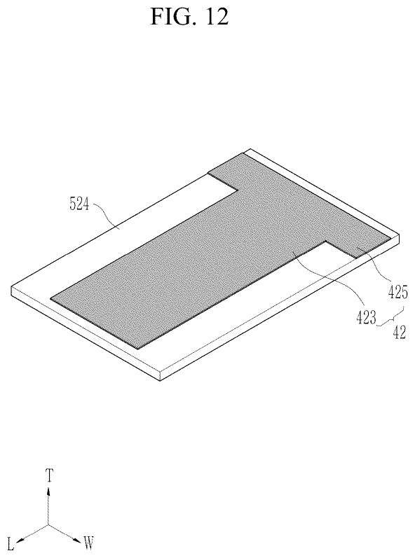

FIG. 10 illustrates a perspective view showing a form in which a multilayer ceramic capacitor according to another embodiment is mounted on a substrate, and FIG. 11 and FIG. 12 each illustrate an exploded perspective view showing an internal electrode structure of the multilayer ceramic capacitor illustrated in FIG. 10.

Referring to FIG. 10 to FIG. 12, the multilayer ceramic capacitor 50 applied to the multilayer ceramic capacitor mounted structure 105 according to the present embodiment includes first and second external electrodes 53 and 54 positioned at opposite ends of a ceramic body 52 in the longitudinal direction, and the ceramic body 52 includes first and second internal electrodes 41 and 42 respectively connected to the first and second external electrodes 53 and 54.

The first and second internal electrodes 41 and 42 are alternately stacked with a dielectric material layer 524 provided therebetween. The first and second internal electrodes 41 and 42 may be formed and stacked on a ceramic sheet forming the dielectric layer 524, and then may be alternately positioned in the ceramic body 52 in the thickness direction with one dielectric layer 524 provided therebetween by firing. The first and second internal electrodes 41 and 42, which are electrodes having different polarities, may be positioned to face each other in a stacking direction of the dielectric layers 524, and may be electrically insulated from each other by the dielectric layer 524 disposed in the middle.

In the present embodiment, the first internal electrode 41 may include a first main surface portion 413, and a first lead portion 415 drawn out to opposite side surfaces of the ceramic body 52 in the width direction W and connected to the first external electrode 53. In addition, the second internal electrode 42 may include a second main surface portion 423, and a second lead portion 425 drawn out to opposite side surfaces along the width direction of the ceramic body 52 and connected to the second external electrode 54.

The first and second external electrodes 53 and 54 may be positioned at opposite end portions of the ceramic body 52 along a longitudinal direction, and may be formed on opposite side surfaces of the ceramic body 52 facing each other in a width direction and upper and lower surfaces of the ceramic body 52 facing each other in a thickness direction. Accordingly, the first and second external electrodes 53 and 54 may not be formed outside the opposite end surfaces of the ceramic body 52.

According to the present embodiment, at opposite ends along the longitudinal direction L of the ceramic body 52, edges of the first and second external electrodes 53 and 54 may be aligned with the outer edges of the first and second electrode pads 121 and 122, and at least the first and second electrode pads 121 and 122 may be positioned more outside than outer edges thereof. That is, the first and second electrode pads 121 and 122 may be positioned to be included in a region that is set between the opposite edges of the multilayer ceramic capacitor 50 in the longitudinal direction L of the ceramic body 52. In this case, the first and second electrode pads 121 and 122 may not be formed outside the opposite edges of the multilayer ceramic capacitor 50 in the longitudinal direction of the ceramic body 52. On the other hand, the first and second electrode pads 121 and 122 may be formed to extend outwardly from the opposite edges of the multilayer ceramic capacitor 50 in the width direction W of the ceramic body 52.

Accordingly, the first and second electrode pads 121 and 122 may be bonded to the first and second external electrodes 53 and 54 on the opposite side surfaces of the ceramic body 52 opposite to each other in the width direction by using the conductive bonding member 131. On the other hand, on the opposite end surfaces of the ceramic body 52 facing each other in the length direction L, the first and second external electrodes 53 and 54 may not be formed, and the conductive bonding member 131 may not be provided, and thus they may not be connected to the first and second electrode pads 121 and 122.

A multilayer ceramic capacitor mounting structure according to another embodiment may be formed by a combination of the multilayer ceramic capacitor having the structure described with reference to FIG. 10 to FIG. 12 and the first and second electrode pads having the structure described with reference to FIG. 8 and FIG. 9, and this is also within the scope of the present disclosure.

On the other hand, in the above-described embodiments, although a mounted structure in which a multilayer ceramic capacitor is mounted in a circuit board has been illustrated and described as an example, the multilayer ceramic capacitor mounted structure according to the present disclosure is not limited thereto, and may be applied to various applicable parts or devices.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

### DESCRIPTION OF SYMBOLS

20, 30, 50: multilayer ceramic capacitor
12, 22, 32, 52: ceramic body
13, 14, 15, 16, 53, 54: external electrode
21, 22, 41, 42: internal electrode
61, 62, 63, 64: insulating layer
101, 102, 103, 104, 105: multilayer ceramic capacitor mounted structure
110: circuit board
121, 122, 221, 222: electrode pad
131: conductive bonding member
133, 143, 153, 163: body portion
135, 145, 155, 165: band portion

What is claimed is:

1. A multilayer ceramic capacitor mounted structure comprising a multilayer ceramic capacitor mounted in an upper surface of a circuit board through first and second electrode pads,
wherein the multilayer ceramic capacitor includes:
a ceramic body including a plurality of dielectric layers stacked on one another and having a preset size with a length, a width, and a thickness along directions crossing each other;
first and second external electrodes spaced apart from each other along a longitudinal direction of the ceramic body, each of the first and second external electrodes being disposed on at least opposite sides in a width direction of the ceramic body; and
a plurality of first and second internal electrodes alternately stacked with the dielectric layers therebetween and respectively connected to the first and second external electrodes in the ceramic body,
wherein edges of the first and second external electrodes are aligned with outer edges of the first and second electrode pads or are positioned at least more outwardly than the outer edges of the first and second electrode pads, at opposite ends along the longitudinal direction of the ceramic body.

2. The structure of claim 1, wherein
the first and second electrode pads are not disposed outside opposite edges of the multilayer ceramic capacitor in the longitudinal direction.

3. The structure of claim 1, wherein
each of the first and second electrode pads includes a pair of patches that are separated from each other based on a center of the ceramic body in a width direction of the ceramic body.

4. The structure of claim 1, wherein
the first and second external electrodes are bonded to the first and second electrode pads, respectively, by a conductive bonding member at opposite sides in a width direction of the ceramic body.

5. The structure of claim 4, wherein
the first and second internal electrodes are positioned to be offset from each other in the longitudinal direction of the ceramic body to be alternately drawn out from opposite end portions thereof,
the first and second external electrodes each include a body portion covering one of the opposite end surfaces of the ceramic body in the longitudinal direction, and a band portion extending from the body portion along at least a side surface of the ceramic body, and
the band portions of the first and second external electrodes are bonded to the first and second electrode pads, respectively, by the conductive bonding member.

6. The structure of claim 5, wherein
the multilayer ceramic capacitor further includes an insulating layer disposed to cover outside of the body portion of each of the first and second external electrodes.

7. The structure of claim 6, wherein
the conductive bonding member is not positioned outside the body portions of the first and second external electrodes on which the insulating layer is disposed.

8. The structure of claim 6, wherein
the band portions of the first and second external electrodes extend from the respective body portions to cover portions of upper and lower surfaces of the ceramic body that face each other in a thickness direction of the ceramic body, and
the insulating layer extends to cover the band portions of the first and second external electrodes disposed on the upper and lower surfaces of the ceramic body.

9. The structure of claim 6, wherein
the band portions of the first and second external electrodes expose portions of upper and lower surfaces of the ceramic body facing each other in a thickness direction of the ceramic body.

10. The structure of claim 6, wherein
the insulating layer is made of at least one material selected from a group including insulating glass, epoxy, and insulating ceramic.

11. The structure of claim 4, wherein
the first internal electrode includes a first main surface portion and a first lead portion drawn out from the first main surface portion to opposite side surfaces of the ceramic body in the width direction and connected to the first external electrode, and
the second internal electrode includes a second main surface portion and a second lead portion drawn out from the second main surface portion to the opposite side surfaces of the ceramic body in the width direction and connected to the second external electrode.

12. The structure of claim 11, wherein
the first and second external electrodes are disposed on at least one of upper and lower surfaces of the ceramic body facing each other in a thickness direction of the ceramic body and on the opposite side surfaces of the ceramic body in the width direction.

13. The structure of claim 11, wherein
the first and second external electrodes are not disposed outside of portions of the opposite end surfaces of the ceramic body facing in the longitudinal direction.

14. A multilayer ceramic capacitor comprising:
a ceramic body including a plurality of dielectric layers stacked on one another and having a preset size with a length, a width, and a thickness along directions crossing each other;
first and second external electrodes spaced apart from each other along a longitudinal direction of the ceramic body, each of the first and second external electrodes including a body portion covering one of opposite end surfaces of the ceramic body in the longitudinal direction, and a band portion extending from the body portion to cover portions of upper and lower surfaces that face each other in a thickness direction of the ceramic body;
a plurality of first and second internal electrodes alternately stacked with the dielectric layers therebetween in the ceramic body, positioned to be offset from each other in the longitudinal direction of the ceramic body to be alternately drawn out from opposite end portions thereof, and respectively connected to the first and second external electrodes; and
an insulating layer disposed to cover outside of the body portions of the first and second external electrodes, and extending to cover the band portions of the first and second external electrodes disposed on the upper and lower surfaces of the ceramic body.

15. The multilayer ceramic capacitor of claim 14, wherein
the band portions of the first and second external electrodes further extend to cover opposite side surfaces of the ceramic body facing each other in a width direction of the ceramic body, and are exposed without being covered with the insulating layer in the width direction.

16. The structure of claim 15, wherein
the first and second external electrodes are not disposed outside of portions of the opposite end surfaces of the ceramic body facing in the longitudinal direction.

17. The multilayer ceramic capacitor of claim 14, wherein
the insulating layer is made of at least one material selected from a group including insulating glass, epoxy, and insulating ceramic.
